(19) United States
(12) Patent Application Publication
(10) Pub. No.: US 2015/0369763 A1
(43) Pub. Date: Dec. 24, 2015

(54) QUANTITATIVE DETERMINATION OF NITROGEN SPECIES DISTRIBUTION IN DISPERSANTS

(71) Applicants: Gordon J. KENNEDY, Washington, NJ (US); Frank Cheng-Yu WANG, Annandale, NJ (US); Steven Webster LEVINE, Flemington, NJ (US); Liepao Oscar FARNG, Lawrenceville, NJ (US); Margaret May-Som WU, Skillman, NJ (US)

(72) Inventors: Gordon J. KENNEDY, Washington, NJ (US); Frank Cheng-Yu WANG, Annandale, NJ (US); Steven Webster LEVINE, Flemington, NJ (US); Liepao Oscar FARNG, Lawrenceville, NJ (US); Margaret May-Som WU, Skillman, NJ (US)

(73) Assignee: ExxonMobil Research and Engineering Company, Annandale, NJ (US)

(21) Appl. No.: 14/728,282

(22) Filed: Jun. 2, 2015

Related U.S. Application Data
(60) Provisional application No. 62/013,765, filed on Jun. 18, 2014.

(51) Int. Cl. G01N 24/08; G01R 33/48; G01R 33/46

(52) U.S. Cl. CPC G01N 24/08; G01R 33/46; G01R 33/4828

(57) ABSTRACT

The distribution of nitrogen species in a long chain alkenyl succinimide dispersants is quantitated and speciated by means of ¹⁵N nuclear magnetic resonance spectroscopy.

### CROSS-REFERENCE TO RELATED APPLICATIONS

This application claims priority to U.S. Provisional Application Ser. No. 62/013,765 filed Jun. 18, 2014, herein incorporated by reference in its entirety.

### FIELD OF THE INVENTION

This invention relates to a method for the quantitative determination of the distribution of nitrogen species in dispersants and more particularly to the quantitative determination of the distribution of nitrogen species by chemical class in dispersants derived from succinic anhydride and polyamines.

### BACKGROUND OF THE INVENTION

The succinimides are ashless, polymeric chemicals widely used as dispersants in a variety of organic fluids, especially those based on petroleum oils, including crude oils, petroleum refinery streams and products such as engine oils to keep sludge, soot, oxidation products, and other particulate deposit precursors dispersed in the oil so that these by-products of heat and combustion do not form fouling deposits either during processing or when in use in engines. They also find use in greases and other fluids and semi-flulds such as inks. Dispersants for different types of application may be referred to by different names. For example, for fuels, they may be called detergents and for lubricants, they are usually described as dispersants or ashless dispersants. Finally for crude oils, they may be called anti-foulant additives. Dispersants of this type are widely available from commercial suppliers such as Lubrizol, Afton, Infineum, BASF and Chevron Oronite.

The succinimides are normally made by first reacting a long chain polymeric alkene based on C₂-C₈ olefin and typically having a number average molecular weight of from about 200 to about 30,000 with an unsaturated aliphatic dicarboxylic acid anhydride. The most common starting materials are polyisobutylene and maleic anhydride. The resulting long chain alkenyl-substituted maleic anhydride is then reacted with a polyamine such as tetraethylene pentamine to form the final succinimide product. The long chain alkenyl group (frequently referred to as an alkyl group) provides a hydrocarbon tail for solubility in a lube oil, crude, or refinery stream; the succinate component links the hydrocarbon tail to the polar head provided by the polyamine portion of the molecule that is believed to attach to the particulate surface. The molecular weight of the final succinimide product is typically 500 to 10,000 Daltons, but more commonly from 1,000 to 3,000 Daltons. The succinimide may be borated by reaction with a borating agent such as boric acid, an ortho-borate, or a meta-borate, for example, trimethyl metaborate (trimethoxyboroxine), triethyl metaborate, tributyl metaborate, trimethyl borate, triethylborate, triisopropyl borate (triisopropoxyborane), tributyl borate (tributoxyborane) or tri-t-butyl borate.

There are numerous patents describing the succinimides and their synthesis; it suffices in view of their widespread production and use to cite only a few exemplary disclosures including, for example, U.S. Pat. No. 4,388,201; U.S. Pat. No. 4,686,054; U.S. Pat. No. 5,211,834; U.S. Pat. No. 6,770,605; U.S. Pat. No. 6,858,070; U.S. Pat. No. 7,329,635.

Commercial dispersants are typically depicted with the idealized bis-imide structure shown below, although mono-imide forms are common as well.

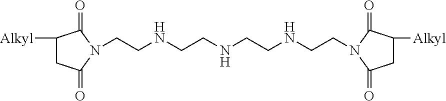

The structures of these dispersants are actually quite complex since the presence of multiple isomers in the polyamine precursor will result in a mixture of products, as shown below:

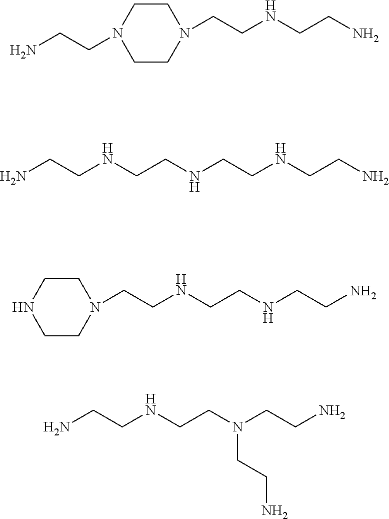 [SMILES: NCCNCCN1CCN(CCN)CC1 ; NCCNCCNCCNCCN ; NCCNCCNCCN1CCNCC1 ; NCCNCCN(CCN)CCN]

Also, incomplete reaction with the succinic anhydride will result in a complex mixture of mono-, bis, and tri-imides. Representative structures that are present in this mixture include the following where SA=succinic anhydride and PAM=polyamine:

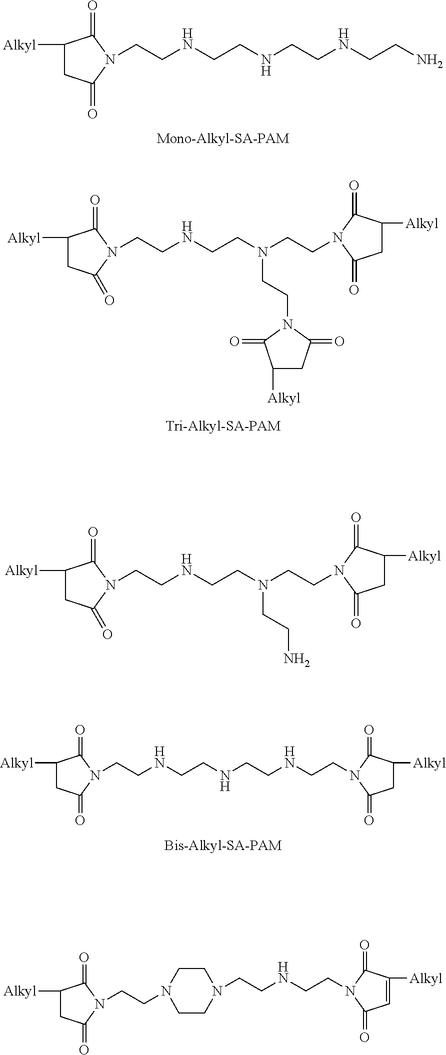

The dispersant properties of these materials are related to the amount of available polar groups (i.e. basic nitrogen) which, in turn, will be a function of the distribution of the various nitrogen species. Information about the various nitrogen species present and their distribution is therefore significant for to the performance of the products and, accordingly, it is desirable to have a fast and economic method of obtaining this information.

Current methods for determining nitrogen species in dispersants are (1) elemental analysis: this method only gives the wt % N and no information on chemical class, e.g. amine, amide, imide and (2) Infrared (IR) spectroscopy: differentiates amides from imides but cannot speciate amine types.

### SUMMARY OF THE INVENTION

We have now found that ¹⁵N Nuclear Magnetic Resonance (NMR) is a useful method for the quantitation and speciation of nitrogen-containing succinimides in that it is capable of determining the distribution of nitrogen species (e.g. amide, imide, and the primary, secondary, and tertiary amine functionalities) in alkyl-SA-PAM type dispersants as well as the amine distribution (i.e. primary, secondary, and tertiary amine) in the polyamine precursors.

According to the present invention, therefore, the distribution of nitrogen species in a long chain alkenyl succinimide is quantitatively determined by means of ¹⁵N Nuclear Magnetic Resonance (NMR) spectroscopy.

The ¹⁵N NMR spectrum can be used to determine the nitrogen species of succinimide compositions for use as dispersants, detergents, anti-foulant additives or, in addition, to serve as tools to differentiate counterfeit additive products used in lubricants, fuels, crude oils, and other petroleum products.

### DRAWINGS

In the accompanying drawings:

FIG. 1 is the ¹⁵N NMR spectrum for tetraethylene pentamine, a representative amine used in the manufacture of succinimide dispersants;

FIG. 2 are the ¹⁵N NMR spectra for tetraethylene pentamine and a succinimide dispersant made with it; and

FIG. 3 are the ¹⁵N NMR spectra for a representative set of succinimide dispersants.

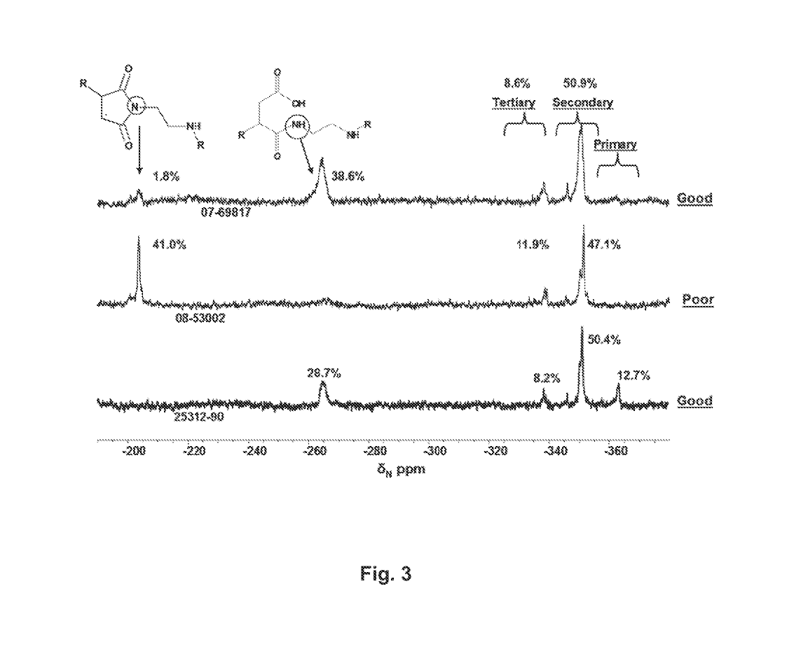

### DETAILED DESCRIPTION

NMR has long been recognized as the spectroscopic technique of choice for obtaining detailed structural, dynamic, and chemical information of organic compounds. For example, high resolution NMR techniques, particularly ¹H and ¹³C, play an important role in the structural characterization of petroleum fractions. When used in combination with other analytical techniques, the average structural information provided by NMR can be applied to develop a detailed structural understanding of organic compounds. ¹⁵N NMR is much less sensitive than ¹H and ¹³C.

Nitrogen-14 and nitrogen-15 are the two stable (non-radioactive) isotopes of the chemical element nitrogen, with nitrogen-14 making up the predominant portion of the two isotopes. Nitrogen-15 is used in nuclear magnetic resonance spectroscopy (NMR), because, unlike the more abundant nitrogen-14 that has an integer nuclear spin and thus a quadrupole moment, N-15 has a fractional nuclear spin of one-half, which offers advantages for NMR like narrower line width. ¹⁵N NMR spectroscopy is a known technique but which has not so far been applied to the quantitation and speciation of nitrogen the functionalities in succinimides. ¹⁵N NMR spectroscopy is described, for example, in Angew Chem. Int. Ed. Engl. 25 (1986) 383-413. The N contents in succinimide dispersants, however, are typically lower by an order of magnitude due to the dilution effect of the high molecular weight alkyl chains. This negatively impacts the sensitivity of the ¹⁵N experiment and makes data collection more challenging. This difficulty can, in most cases, be addressed with a combination of longer data collection times (16-48 hours) and addition of the relaxation agent.

The ¹⁵N chemical shifts useful in the spectral analysis of the succinimides are to be found in the range of −200 to −400 ppm (referenced with respect to formamide (90% v/v in DMSO-d₆) as an external reference standard with δ_{N}=−268 ppm). Primary, secondary and tertiary amines shifts appear in the range of about −360 to −330 ppm, with the secondary and tertiary amine groups respectively further downfield from the primary groups; amide shifts occur at around −260 ppm and imide groups at about −200 ppm. This information is potentially of substantial utility for the dispersant functionality since it has been found that the extent of imidization may be related to the ability to function as a dispersant. In the synthesis of the succinimides from the polyamine and the maleic anhydride, incomplete reaction will result in a complex mixture of mono-, bis-, and tri-imides. Representative structures that are present in this mixture include the following:

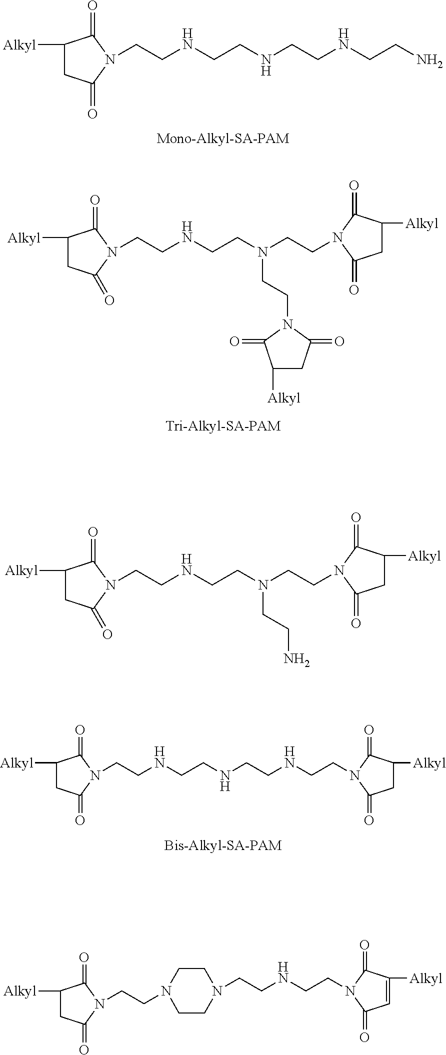

The dispersant properties of these materials are potentially related to the amount of available polar groups (i.e. basic nitrogen) which, in turn, will be a function of the distribution of the various nitrogen species. An additional, structural subtlety that was discovered as part of this ¹⁵N Nuclear Magnetic Resonance (NMR) methodology is the presence of amide functionalities that result from incomplete ring closure in the imidization reaction, with consequential effects on the functionality of the succinimide as a dispersant.

### EXAMPLES

Selected polyamine and succinimide samples were subjected to ¹⁵N NMR. Data were recorded on ˜50% w/w solutions in CDCl₃ (sample concentration used was dependent on sample availability) at a sample temperature of 50° C. using a standard 10 mm broadband probe on a Varian NMRS500 NMR spectrometer (499.888 MHz ¹H and 50.657 MHz ¹⁵N frequencies, respectively). To save time ¹⁵N NMR data were recorded on samples, wherever possible, that were doped with 0.5% w/w chromium(III) acetylacetonate as relaxation agent. The ¹⁵N NMR data were recorded with ¹H decoupling and no Nuclear Overhauser Enhancement (NOE). ¹⁵N NMR acquisition parameters used for doped samples were a π/2 pulse, a repetition rate of 3.1 s, spectral width of 20 kHz, and 32 k data points. For those samples that needed to be reconstituted for subsequent analyses ¹⁵N NMR data were recorded on undoped samples. This necessitated the use of a much longer pulse delay to ensure complete spin lattice relaxation and quantitative reliability. Parameters used for the undoped samples were a π/2 pulse, a repetition rate of 30.1 s, spectral width of 20 kHz, and 32 k data points. Data collection times are dependent on sample concentration, N content, and if CrIII(acac) is used, and typically ranged from ˜1-4 hours to several days. The ¹⁵N NMR free induction decays (FID) were Fourier transformed typically with 1.0 Hz line broadening and phased in a consistent fashion to yield the corresponding ¹⁵N NMR spectra. All ¹⁵N NMR spectra were piecewise-integrated and the integrals normalized to give the percentage of nitrogen in each spectral region. A representative set of these integration data are tabulated in Appendix 1. All ¹⁵N chemical shifts are referenced with respect to formamide (90% v/v in DMSO-d₆) as an external reference standard with δ_{N}=−268 ppm.

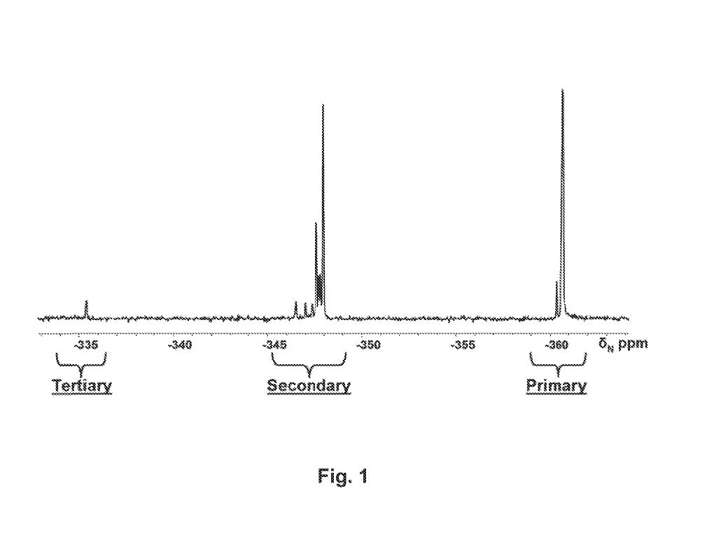

FIG. 1 is a representative ¹⁵N NMR spectrum of tetraethylene pentamine, a polyamine typically used in the synthesis of alkyl-SA-PAM dispersants. This particular spectrum shows three sets of peaks corresponding to primary, secondary, and tertiary amines (—C—NH₂, —(C—)₂NH, and —(C—)₃N) in the ratio of 0.409:0.476:0.115. The fine structure in the spectrum reflects the sensitivity of the chemical shift to subtle structural differences in each of the isomers as noted above. The data in FIG. 1 illustrates the power of this technique to assess differences in the average structural composition of polyamines that is difficult to determine by other techniques.

A quantitative ¹⁵N spectrum, such as the one in FIG. 1, can be recorded on a polyamine sample with a N content of ˜37 wt % in a matter of minutes to hours. The lower N content of the succinimide results in lower overall sensitivity that, in most cases, can be addressed with a combination of longer data collection times (16-48 hours) and addition of the relaxation agent.

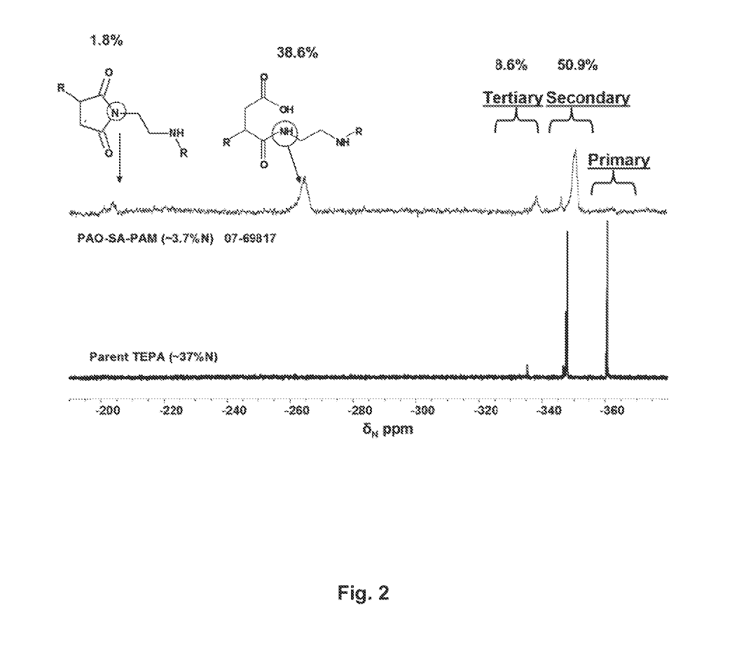

FIG. 2 illustrates the ¹⁵N NMR spectra for a tetraethylene pentamine precursor and for the corresponding succinimide dispersant (PAO-SA-PAM) formed from it with a final N content of ˜3.7wt %.

Comparison of the polyamine precursor and the PAO-SA-PAM spectra in FIG. 5 reveal several structural features of potential significance in understanding dispersant properties. For example, reaction of the polyamine with the succinic anhydride results in complete conversion of the primary amine functionalities. This means that there are no mono-imide adducts present in this material. However, the imidization reaction is incomplete as evidenced by the strong amide resonance at −263 ppm and much weaker imide resonance at −200 ppm. Complete reaction of the primary amines is further confirmed by the observation that the sum of amide and imide functionalities agrees well with the NH₂ content in the polyamine precursor (40.4% vs. 41.0%).

These data indicate different N distributions among the additives. For example, one of the three materials (08-53002) which was completely imidized showed poor performance in lab scale screening. In the case of the 25512-90 material no evidence of imidization and incomplete reaction of the primary amine were observed and this material demonstrated good performance in lab scale screening. Imide levels of less than 40 percent and preferably less than 20 or 10 or even 5 percent therefore appear favorable for dispersant functionality.

1. A method of quantitating and speciating the nitrogen compounds in a succinimide which comprises subjecting the succinimide to ¹⁵N nuclear magnetic resonance Spectroscopy (¹⁵N NMR) to produce a ¹⁵N NMR spectrum of the distribution of nitrogen species in the succinimide.

2. A method according to claim 1 in which ¹⁵N chemical shifts of the succinimide are in the range of −200 to −400 ppm (referenced with respect to formamide (90% v/v in DMSO-d₆) as an external reference standard with δ_{N}=−268 ppm).

3. A method according to claim 1 in which ¹⁵N chemical shifts of primary amine groups of the succinimide are in the range of −360 to −335 ppm (referenced with respect to formamide (90% v/v in DMSO-d₆) as an external reference standard with δ_{N}=−268 ppm).

4. A method according to claim 1 in which ¹⁵N chemical shifts of primary, secondary and tertiary amine groups of the succinimide are in the range of about −360 to −330 ppm (referenced with respect to formamide (90% v/v in DMSO-d₆) as an external reference standard with δ_{N}=−268 ppm).

5. A method according to claim 1 in which ¹⁵N chemical shifts of secondary and tertiary amine groups of the succinimide are downfield of the shifts of primary amine groups in the succinimide.

6. A method according to claim 1 in which ¹⁵N chemical shifts of amide groups of the succinimide are in the range of about −260 ppm (referenced with respect to formamide (90% v/v in DMSO-d₆) as an external reference standard with δ_{N}=−268 ppm).

7. A method according to claim 1 in which ¹⁵N chemical shifts of imide groups of the succinimide are in the range of about −200 ppm (referenced with respect to formamide (90% v/v in DMSO-d₆) as an external reference standard with δ_{N}=−268 ppm).

8. A method according to claim 1 in which the succinimide has an imide content of not more than 20 percent.

9. A method according to claim 1 in which the succinimide has an imide content of not more than 5 percent.

10. A method according to claim 1 which is carried out in the presence of a relaxation agent.

11. A method according to claim 1 which is carried out in the absence of a relaxation agent.

12. A method according to claim 1 in which the succinimide is a bis-imide.

13. A method according to claim 1 in which the succinimide is a borated succinimide.
